(19) United States
(12) Patent Application Publication
(10) Pub. No.: US 2006/0231935 A1
(43) Pub. Date: Oct. 19, 2006

(54) BGA type semiconductor package featuring additional flat electrode teminals, and method for manufacturing the same

(75) Inventor: Koji Nishida, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 11/402,008

(22) Filed: Apr. 12, 2006

(30) Foreign Application Priority Data
Apr. 13, 2005 (JP) 205-115664

(51) Int. Cl. H01L 23/02

(52) U.S. Cl. 257/678

(57) ABSTRACT

In a semiconductor package including a wiring board having a top surface, a bottom surface and a side face. The bottom surface is divided into a central area, and a peripheral area surrounding the central area. A semiconductor chip is mounted on the top surface of the wiring board so as to be electrically connected to a wiring pattern layer of the wiring board. An array of metal balls is provided as electrode terminals in the central area on the bottom surface of the wiring board. A plurality of additional electrode terminals are provided in the peripheral area on the bottom surface and/or the side face of the wiring board.

### BACKGROUND OF THE INVENTION

1. Field of the Invention

The present invention relates to a ball grid array (BGA) type semiconductor package, and a method for manufacturing such a BGA type semiconductor package.

2. Description of the Related Art

A prior art method for manufacturing a BGA type semiconductor package will be now explained below.

First, a wiring board, which is called a package board or an interposer, is prepared. The wiring board usually features a multi-layered wiring structure including a plurality of insulating layers, and each of the insulating layers has a wiring pattern layer formed on a top surface thereof. Two adjacent wiring pattern layers are connected to each other through a plurality of through holes formed in the insulating layer therebetween. The lowermost insulating layer has a plurality of flat electrode pads formed on a bottom surface thereof, and the flat electrode pads are arranged in a matrix manner. In short, the flat electrode pads formed on the bottom surface of the lowermost insulating layer are connected to the wiring pattern layer formed on the top surface of the uppermost insulating layer through the intermediary of the through holes formed in the lowermost and intermediate insulating layers and the wiring pattern layers formed on the lowermost and intermediate insulating layers.

Next, a semiconductor chip (bare chip) is mounted on the top surface of the wiring board, and is connected to the top wiring pattern layer formed on the top surface of the wiring board with, for example, bonding wires.

Finally, the semiconductor chip and the wiring pattern layer are sealed with a molded resin enveloper, and a plurality of electrode terminals or metal balls are adhered to the respective flat electrode pads formed the bottom surface of the lowermost insulating layer, resulting in production of the BGA type semiconductor package.

The above-produced BGA type semiconductor package is mounted as one of various electronic products on a motherboard for a piece of electronic equipment, such that the metal balls of the package are correspondingly contacted with and adhered to flat electrode pads formed and arranged on the motherboard. Thus, a mounting area on the motherboard, which is occupied by the BGA type semiconductor package, is relatively small, because the BGA type semiconductor package has no lead terminals extending outward from sides of the package. Namely, the BGA type semiconductor package has been developed to meet the demands of higher performance, smaller and lighter size, and higher speed for a small piece of electronic equipment, such as a mobile phone terminal, a personal digital assistant (PDA), a note-type personal computer or the like.

Thus, a plurality of BGA type semiconductor packages are commercially shipped and circulated for production of various pieces of electronic equipment. For the shipping and circulation, the BGA type semiconductor packages are stored in a tray having a plurality of recesses, in which the BGA type semiconductor packages are respectively received such that an array of the metal balls of each of the BGA type semiconductor package is protected from being subjected to damage.

In particular, each of the recesses of the tray has a peripheral shallow recess section for fittingly receiving a peripheral area of the bottom surface of a BAG semiconductor package (i.e., a wiring board), and a central deep recess section for receiving the array of the metal ball of the package. Namely, each of the BAG semiconductor packages is received in the corresponding recess such that the peripheral area on the bottom surface of the wiring board rests on the peripheral shallow recess section, with the array of the metal balls received in the central deep recess section being protected from being subjected to damage.

In other words, conventionally, the array of the metal balls must be confined within a central area on the bottom surface of the wiring board. Namely, no metal balls are arranged on the peripheral area on the bottom surface of the wiring board.

On the other hand, before the BGA type semiconductor packages are commercially shipped and circulated, a test operation is carried out to determine whether each of the BGA type semiconductor packages is properly operating, using a test apparatus. This test operation is carried out by setting a BGA type semiconductor package in a socket of the test apparatus. In this case, it is preferable to confine the array of the metal balls within the central area on the bottom surface of the wiring board, because a metal ball arranged on the peripheral area on the bottom surface of the wiring board is susceptible to being damaged when the BGA type semiconductor package is set in the socket.

In short, in the above-mentioned BGS semiconductor package, the peripheral area on the bottom surface of the wiring board is defined as a metal-ball exclusion area, and the array of the metal balls is confined within the central area on the bottom surface of the wiring board.

### SUMMARY OF THE INVENTION

It has now been discovered that the above-mentioned prior art method has a problem to be solved as mentioned hereinbelow.

With the recent advance of integration of semiconductor chips, in a BAG semiconductor package, a number of metal balls to be provided on the bottom surface of the wiring board become larger. In this case, since a minimum pitch of the array of the metal balls is previously determined, it is necessary to enlarge the wiring board so that the large number of the metal balls can be arranged on the central area on the bottom surface of the wiring board.

For example, in JP-H10-284637-A and JP-2004-014877-A, it is proposed that additional lead terminals are projected from sides of a BGA type semiconductor package without enlarging a wiring board. However, this proposal is not satisfactory because of an increase in a mounting area for the BAG semiconductor package due to the projection of the additional lead terminals from the sides of the package.

Further, in JP-2004-022664-A, it is proposed that additional small flat electrode pads, which are used for only testing a BGA type semiconductor package, are arranged between metal balls without enlarging a wiring board. However, this proposal is also not satisfactory because the metal balls are susceptible to being damaged by test probes during the testing.

In accordance with a first aspect of the present invention, there is provided a semiconductor package which includes a wiring board having a top surface, a bottom surface and a side face, the bottom surface being divided into a central area, and a peripheral area surrounding the central area. A semiconductor chip is mounted on the top surface of the wiring board so as to be electrically connected to a wiring pattern layer of the wiring board, and an array of metal balls is provided as electrode terminals in the central area on the bottom surface of the wiring board. A plurality of additional electrode terminals are provided in the peripheral area on the bottom surface and/or the side face of the wiring board.

The wiring pattern layer may be formed on the top surface of the wiring board.

The semiconductor package may further include an enveloper formed on the top surface of the wiring board so as to encapsulate the semiconductor chip.

Each of the additional electrode terminals may feature a flat face which is coplanar with the bottom surface of the wiring board.

The additional electrode terminals may be arranged along a side of the wiring board, and each of the additional electrode terminals may feature a flat face which is coplanar with the side face of the wiring board. In this case, each of the additional electrode terminals may further feature another flat face which is coplanar with the bottom surface of the wiring board.

Each of the additional electrode terminals may be configured as an elongated electrode terminal extending along the side of the wiring board. In this case, the elongated electrode terminal may further feature a flat face which is coplanar with the bottom surface of the wiring board. Also, the elongated electrode terminal may feature another flat face which is coplanar with the side face of the wiring board.

Each of the additional electrode terminals may be configured as a semi-circular electrode terminal in the side of the wiring board. In this case, the semi-circular electrode terminal may further feature a semi-cylindrical face which is formed as a recessed face in the side face of the wiring board.

In accordance with a second aspect of the present invention, there is provided a method for manufacturing a semiconductor package, which comprises the steps of preparing a wiring board substrate on which a wiring board area is defined, the wiring board substrate having a wiring pattern layer provided at the wiring board area, and an array of electrode pads formed in a central area on a bottom surface of the wiring board area; mounting a semiconductor chip on a top surface of the wiring board substrate at the wiring board area; forming a plurality of openings in the wiring board substrate along boundaries defining the wiring board area; at least partially stuffing the openings with an electrical conductive material; and cutting the wiring board substrate along the boundaries defining the wiring board area.

The method may further comprise the step of encapsulating the wiring pattern layer and the semiconductor chip with a molded resin, with the molded resin being simultaneously cut during the cutting of the wiring board substrate. Also, the method may further comprise the step of adhering metal balls to the respective electrode pads.

In the method, the formation of the openings and the at least partially stuffing of the openings may be carried out prior to the mounting of the semiconductor chip.

In the method, the at least partially stuffing of the openings may be carried out so that the openings are completely stuffed with the electrical conductive material.

In the method, the at least partially stuffing of the openings may be carried out so that an electrical conductive layer is formed on an inner face of each of the openings.

The method may further comprise the step of forming the wiring layer on the top surface of the wiring surface substrate at the wiring board area.

### BRIEF DESCRIPTION OF THE DRAWINGS

The present invention will be more clearly understood from the description set forth below, with reference to the accompanying drawings, wherein;

FIG. 1A is a perspective view of a prior art BGA type semiconductor package;

FIG. 1B is a perspective view showing the prior art BGA type semiconductor package of FIG. 1A in an upside down manner;

FIGS. 2A through 8A are bottom views for explaining an embodiment of the method for manufacturing a BGA type semiconductor package according to the present invention;

FIGS. 2B through 8B are cross-sectional views taken lo along the B-B lines of FIGS. 2A through 8A, respectively;

FIG. 9 is a cross-sectional view showing the BGA type semiconductor package of FIGS. 8A and 8B mounted on a motherboard;

FIG. 10A is a bottom view showing a first modification of the BGA type semiconductor package of FIGS. 8A and 8B;

FIG. 10B is a partial perspective view of the BGA type semiconductor package of FIG. 10A; and

FIGS. 11 through 14 are respective bottom views showing second, third, fourth and fifth modifications of the BGA type semiconductor package of FIGS. 8A and 8B.

### DESCRIPTION OF THE PREFERRED EMBODIMENT

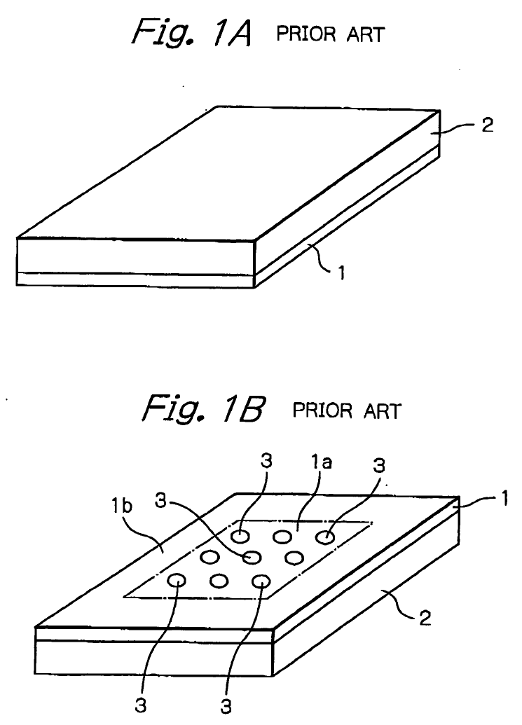

Before the description of the preferred embodiment of the present invention, for better understanding of the present invention, a prior art BGA type semiconductor package will be now explained with reference to FIGS. 1A and 1B.

Referring to FIG. 1A, the BGA type semiconductor package includes a rectangular wiring board 1 which is called a package board or an interposer, and which is composed of a suitable resin material such as epoxy resin. Although not visible in FIG. 1A, the wiring board 1 has a wiring pattern layer formed on a top surface thereof, and a semiconductor chip (bare chip) is mounted on the top surface of the wiring board 1 such that electrical connections are established between the semiconductor chip and the wiring pattern layer. After the establishment of the electrical connections, the semiconductor chip and the wiring pattern layer are sealed with a molded resin enveloper 2.

As shown in FIG. 1B illustrating the BGA type semiconductor package of FIG. 1A in an upside-down manner, a central rectangular area 1a and a peripheral rectangular area 1b are defined on the bottom surface of the wiring board 1. Note, in FIG. 1B, a boundary between the central rectangular area 1a and the peripheral rectangular area 1b is conceptually shown by a one-dot chain line.

A plurality of flat electrode pads (not shown) are formed on the central rectangular area 1a so as to be arranged in a matrix manner, and a plurality of electrode terminals or metal balls 3 are adhered to the respective flat electrode pads. The flat electrode pads are electrically connected to the wiring pattern layer through the intermediary of via plugs formed in the wiring board 1, to thereby establish electrical connections between the semiconductor chip and the metal balls 3.

In the prior art BGA type semiconductor package, no flat electrode pads are formed on the peripheral rectangular area 1b of the wiring board 1, and thus no metal balls are provided on the peripheral rectangular area 1b. Namely, the peripheral rectangular area 1b on the bottom surface of the wiring board 1 is defined as a metal-ball exclusion area, for the reasons discussed hereinbefore.

Accordingly, when the number of the metal balls 3 to be provided on the central rectangular area 1a is increased, it is necessary to enlarge the wiring board 1.

Note, in FIG. 1B, although only the nine metal balls 3 are shown for the sake of convenience of illustration, in reality, a large number (e.g. more than 500) of metal balls 3 are provided in the central rectangular area 1a.

### Embodiment

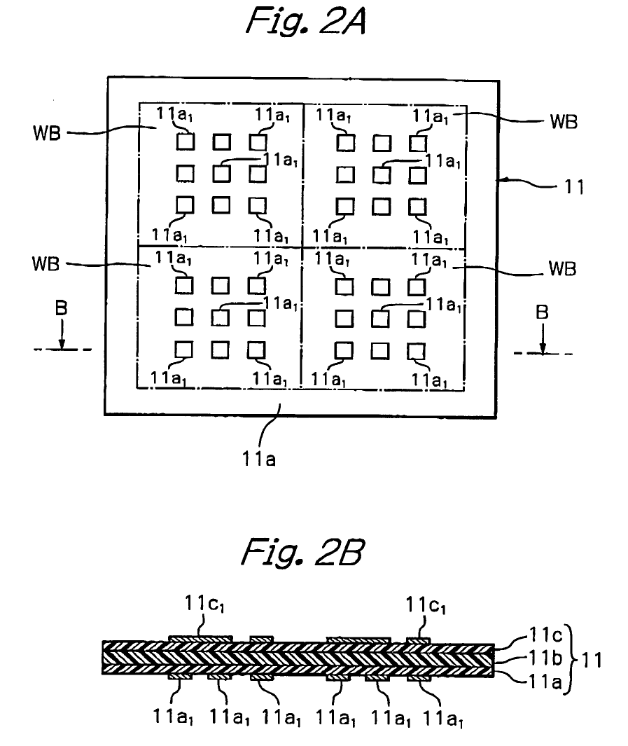

Next, with reference to FIGS. 2A through 8A and FIGS. 2B through 8B, an embodiment of the method for manufacturing a BGA type semiconductor package according to the present invention is explained below. Note, FIGS. 2A through 8A are bottom views for explaining this embodiment, and FIGS. 2B through 8B are cross-sectional views taken along the B-B lines of FIGS. 2A through 8A, respectively.

Referring to FIGS. 2A and 2B, four wiring board areas WB are previously defined over the multi-layered wiring board substrate 11 so as to be adjacent to each other, as conceptually shown by one-dot chain lines in FIG. 2A. As stated hereinafter, the multi-layered wiring board substrate 11 is cut along the one-dot chain lines, and the wiring board areas WB are separated from each other into four wiring boards.

Although not shown in FIG. 2A, the multi-layered wiring board substrate 11 includes three insulating layers: a lowermost insulating layer 11a, an intermediate insulating layer 11b and an uppermost insulating layer 11c, which are stacked in order, and each of the insulating layers 11a, 11b and 11c may be composed of a suitable resin material such as epoxy resin.

The lowermost insulating layer 11a has four sets of flat electrode pads 11a₁ formed on a bottom surface thereof, and the four sets of flat electrode pads 11a₁ are arrayed in a matrix manner in central rectangular areas defined on the respective wiring board areas WB. Each of the flat electrode pads 11a₁ may be composed of a suitable metal material such as copper (Cu), and the formation of the flat electrode pads 11a₁ may be carried out by using a photolithography and etching process.

On the other hand, although not shown in FIG. 2A, the uppermost insulating layer 11c has four wiring pattern layers 11c₁ formed on a top surface thereof, and the wiring pattern layers are arranged in the respective wiring board areas WB. Each of the wiring pattern layers 11c₁ may be composed of a suitable metal material such as copper (Cu), and the formation of the wiring pattern layer 11c₁ may be carried out by using a photolithography and etching process.

Although not shown in FIG. 2B, each of the lowermost and intermediate insulating layer 11a and 11b has four wiring pattern layers formed on a top surface thereof, and the wiring pattern layers are arranged in the respective wiring board areas WB. Similarly, each of these wiring pattern layers may be composed of a suitable metal material such as copper (Cu), and the formation of the wiring pattern layer may be carried out by using a photolithography and etching process.

Each set of flat electrode pads 11a₁ are connected to the wiring pattern layer formed on the lowermost insulating layer 11a through a plurality of through holes (not shown) formed in the lowermost insulating layer 11a, and then the wiring pattern layer formed on the lowermost insulating layer 11a is connected to the wiring pattern layer formed on the intermediate insulating layer 11b through a plurality of through holes (not shown) formed in the intermediate insulating layer 11b. Similarly, the wiring pattern layer formed on the intermediate insulating layer 11b is connected to the wiring pattern layer 11c formed on the uppermost insulating layer 11c through a plurality of through holes (not shown) formed in the uppermost insulating layer 11c. Note, each of the though holes is stuffed with a suitable metal material such as copper (Cu)

Note, in FIG. 2A, although the nine flat electrode pads 11a₁ are shown in each of the wiring board areas WB for the sake of convenience of illustration, in reality, a large number (e.g. more than 500) of flat electrode pads are provided in each of the wiring board areas WB.

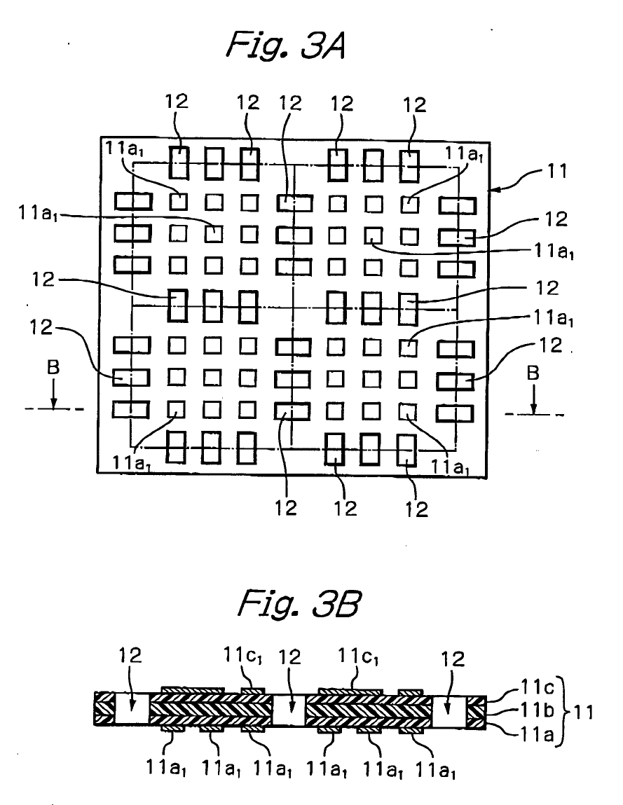

Next, referring to FIGS. 3A and 3B, a plurality of rectangular openings 12 are mechanically formed in the multi-layered wiring board substrate 11 along the one-dot chain lines or boundaries defining the wiring board areas WB. Namely, each of the rectangular openings 12 is arranged so that the corresponding one-dot chain line passes through a center of the rectangular opening 12 concerned. In other words, each of the boundaries defining the wiring board areas WB is included in a corresponding rectangular opening 12. The formation of the rectangular openings 12 may be carried out by using a suitable mechanical processing machine such as a drilling machine.

Note, although not illustrated in FIG. 3B, at least one of the wiring pattern layers (e.g. 11c₁), which are formed on the respective insulating layers 11a, 11b and 11c, and which are included in each of the wiring board areas WB, is partially exposed to the exterior on an inner side face defining a corresponding rectangular opening 12.

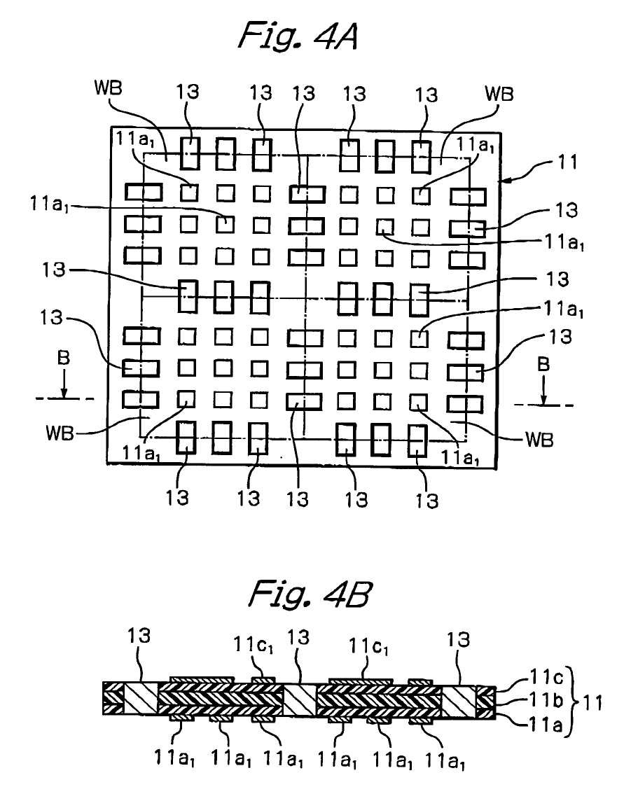

Next, referring to FIGS. 4A and 4B, each of the rectangular openings 12 is stuffed with a suitable metal material 13 such as copper (Cu) by using, for example, a copper electroless plating process. At this time, each of the stuffed metal materials 13 is suitably connected to at least one of the wiring pattern layers (e.g. 11c₁), which is exposed on the inner side face defining the corresponding rectangular opening 12.

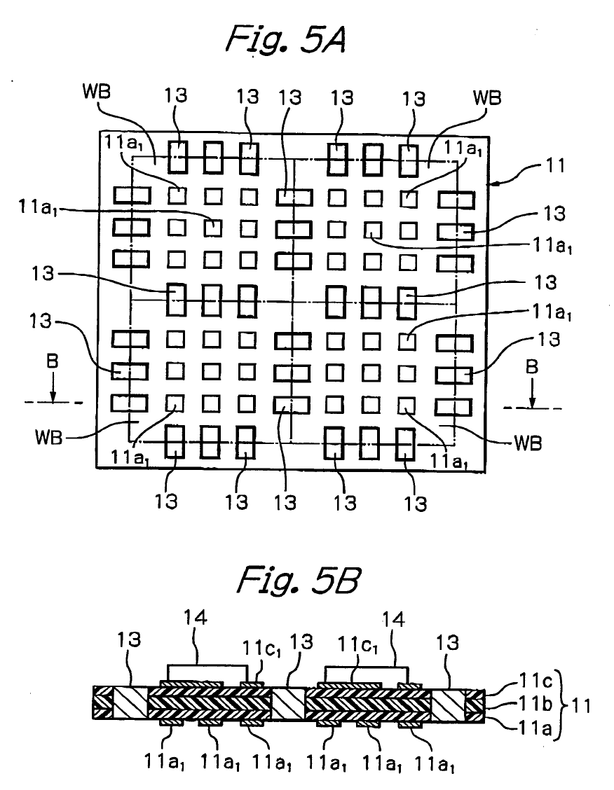

Next, referring to FIGS. 5A and 5B, semiconductor chips 14 (bare chips) are mounted on the uppermost insulating layer 11c at the respective wiring board areas WB, and each of the semiconductor chips 14 is connected to a corresponding wiring pattern layer 11c₁ with, for example, bonding wires (not shown). In this case, local areas on the wiring pattern layer 11c₁, to which the respective bonding wires should be bonded, may be plated with gold (Au), to thereby ensure a secure bonding between the wiring pattern layer 11c₁ and the bonding wires. This gold plating process may be carried out as an electroplating process immediately after the wiring pattern layer 11c₁ on the uppermost insulating layer 11c is completed, and the gold-plated layer may have a thickness falling within a range from 0.2 to 1 μm. Of course, during the gold plating process, the remaining areas on the wiring pattern layer 11c₁ except for the aforesaid local areas are suitably masked.

Each of the semiconductor chips 14 may be of a flip-chip (FC) type featuring an array of metal bumps provided on a top surface thereof. In this case, each of the wiring pattern layers 11c₁ includes an array of electrode pads corresponding to the array of metal bumps, and the FC type semiconductor chip 14 is flipped over and is mounted on the array of electrode pads so as to establish electrical connections between the array of metal bumps and the array of electrode pads. If necessary, the electrode pads may be plated with gold (Au), to thereby ensure secure electrical connections between the metal bumps and the electrode pads.

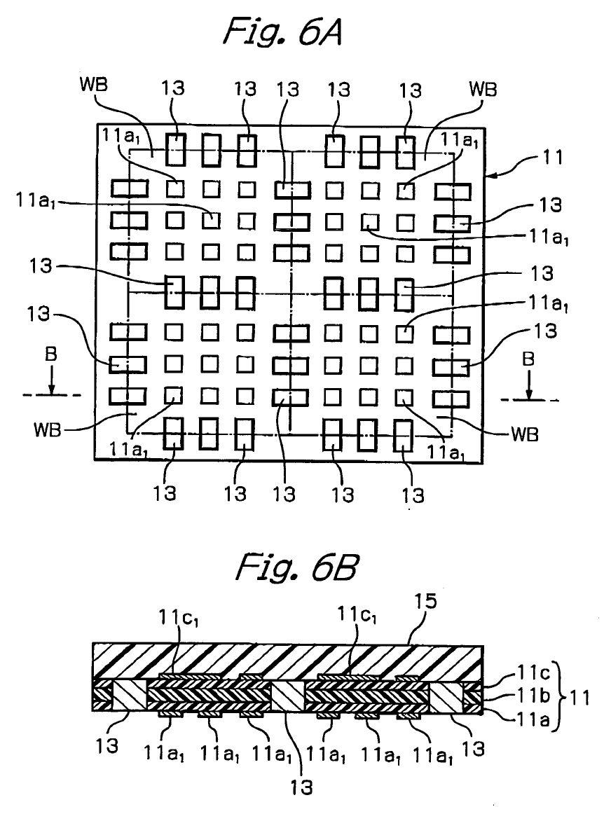

Next, referring to FIGS. 6A and 6B, the semiconductor chips 14 and the wiring pattern layers 11c₁ are sealed with a molded resin 15, which may be composed of a suitable resin material such as epoxy. Then, both the multi-layered wiring board substrate 11 and the molded resin 15 are subjected to a dicing process in which they are cut along the one-dot chain lines defining the wiring board areas WB, by using a cutting apparatus having a rotary cutting blade, whereby the four semiconductor packages can be obtained. Note, the dicing process may be carried out by using a punching apparatus.

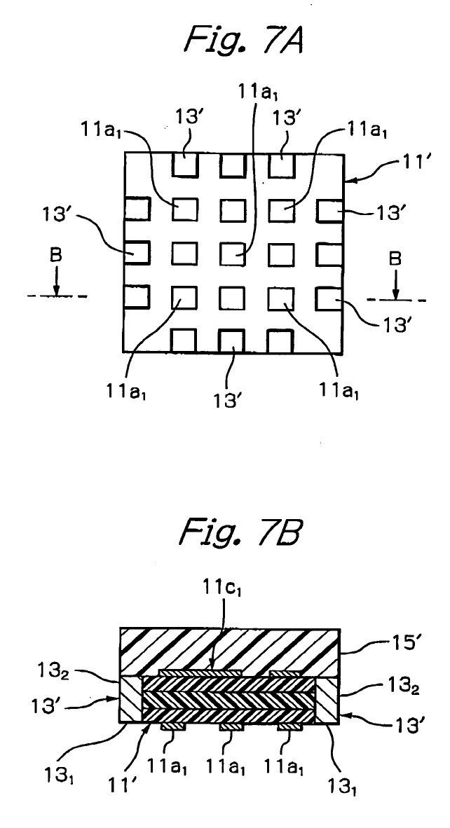

Next, referring to FIGS. 7A and 7B, which representatively illustrate one of the semiconductor packages obtained by the aforesaid dicing process, each of the semiconductor packages includes a wiring board 11′ derived from the multi-layered wiring board substrate 11, and a resin enveloper 15′ derived from the molded resin 15 and encapsulating the semiconductor chip 14 and the wiring pattern layer 11c₁ (see FIG. 5B). Also, the semiconductor package features a plurality of flat electrode terminals 13′ derived from the stuffed copper materials 13 and provided along the sides of the wiring board 11′. Each of the flat electrode terminals 13′ features a flat face 13₁ which is coplanar with the bottom surface of the wiring board 11′, and a flat face 13₂ which is coplanar with a corresponding side face of the wiring board 11′.

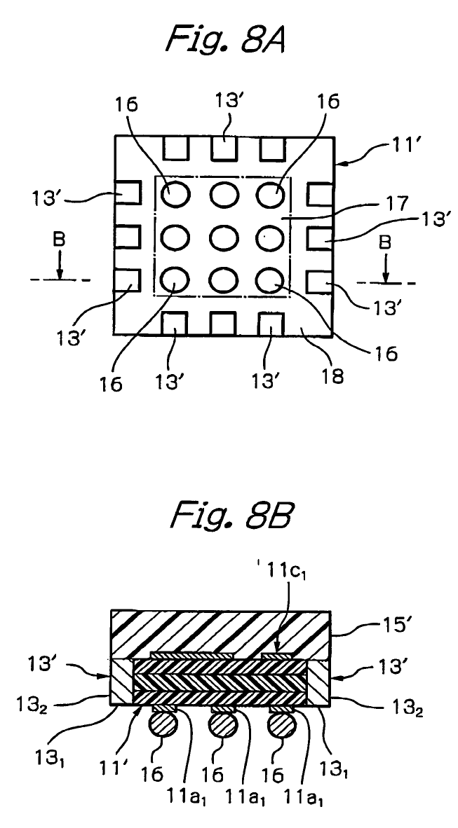

Finally, referring to FIGS. 8A and 8B, metal balls 16, which may be formed as solder balls, are adhered to the respective flat electrode pads 11a₁, resulting in completion of production of the BGA type semiconductor package. In this case, the flat electrode pads 11a₁ may be plated with gold (Au), to thereby ensure a secure adhesion of the metal or solder balls 16 to the respective flat electrode pads 11a₁. This gold plating process may be carried out as an electroplating process immediately after the above-mentioned dicing process (see: FIGS. 7A and 7B) is completed, and the gold-plated layer may have a thickness falling within a range between from 0.05 to 0.1 μm. At this time, the flat faces 13₁ and 13₂ of the flat electrode terminals 13′ may be also plated with gold (Au).

Although not shown in FIG. 8B, the array of the solder balls 16 is confined within a central rectangular area 17 on the bottom surface of the wiring board 11′, and the flat electrode terminals 13′ are arranged in a peripheral rectangular area 18 surrounding the central rectangular area 17, with a boundary between the central rectangular area 17 and the peripheral area 18 being conceptually shown by a one-dot chain line. Namely, the peripheral rectangular area 18 is defined as a metal-ball exclusion area, but the arrangement of the flat electrode terminals 13′ in the peripheral rectangular area 18 is allowed.

In the BGA type semiconductor package of FIGS. 8A and 8B, not only can the solder balls 16 serve as electrode terminals, but also the flat electrode terminals 13′ serve as additional electrode terminals. Thus, it is possible to considerably increase the number of electrode terminals without enlarging the wiring board 11′. A part of the flat electrode terminals 13′ may be used as electrode terminals for testing the BGA type semiconductor package. Also, another part of the flat electrode terminals 13′ may be used as electrode terminals for a power supply or a grounding. Further, yet another part of the flat electrode terminals 13′ may be used as electrode terminals for transmission of signals.

Also, in the BGA type semiconductor package of FIGS. 8A and 8B, when the number of the solder balls 16 is more than 500, the peripheral rectangular area or metal-ball exclusion area 18 may have a width falling a range from 0.5 to 1 mm, and each of the flat faces 13₁ and 13₂ of the flat electrode terminals 13′ may have a dimension on the order of 0.5 mm.

Further, in the BGA type semiconductor package of FIGS. 8A and 8B, the wiring board 13′ may have a thickness falling within a range from 0.29 to 0.33 mm, and the solder balls 16 are arranged and arrayed at a pitch on the order of 0.5 mm. In this case, the BGA type semiconductor package may be called a fine pitch ball grid array (FPBGA) type semiconductor package.

In the above-mentioned method, the formation of the rectangular openings 12 in the multi-layered wiring board substrate 11 and the stuffing of the rectangular openings 12 with the metal material may be carried out prior to the mounting of the semiconductor chips 14 on the uppermost insulating layer 11c at the respective wiring board areas WB, if necessary.

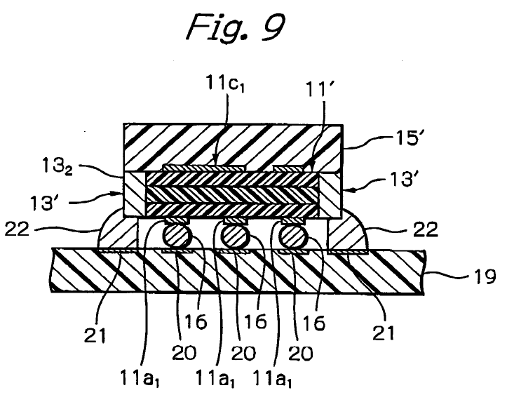

With reference to FIG. 9, the BGA type semiconductor package of FIGS. 8A and 8B is illustrated as being mounted on a motherboard 19 for a piece of electronic equipment. The motherboard 19 has a plurality of flat electrode pads 20 formed on a top surface thereof, and the flat electrode pads 20 are arrayed so as to have a mirror image relationship with respect to the array of the solder balls 16. Further, the motherboard 19 has a plurality of flat electrode pads 21 formed on the top surface thereof, and the flat electrode pads 21 are correspondingly arranged with respect to the arrangement of the flat electrode terminals 13′. Also, a pinch of solder 22 is placed on and adhered to each of the flat electrode pads 21.

For mounting of the BGA type semiconductor package on the motherboard 19, first, the package is placed on the motherboard 19 so that the solder balls 16 are in contact with the respective flat electrode pads 20, and so that the flat electrode terminals 13′ are in contact with the pinches of solder 22. Then, the solder balls 16 and the pinches of solder 22 are thermally reflowed by exposing them to a heated gas, resulting in fixture of the solder balls 16 to the flat electrode pads 20, and in fixture of the flat electrode terminals 13′ to the pinches of solder 22.

First Modification

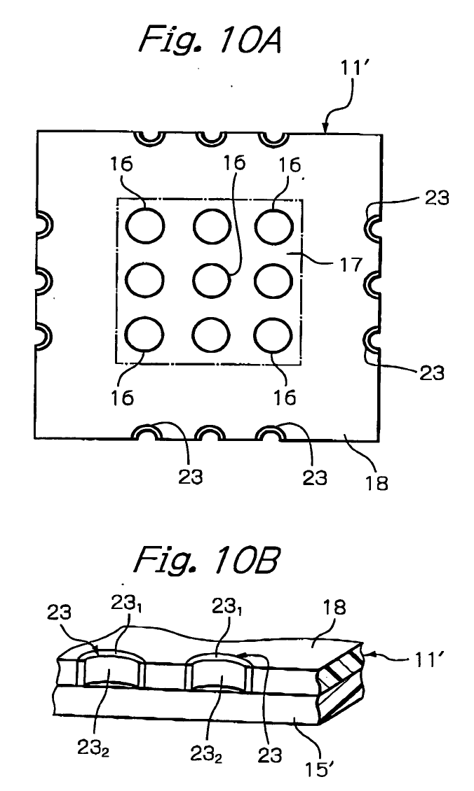

FIGS. 10A and 10B show a first modification of the BGA type semiconductor package of FIGS. 8A and 8B. Note, FIG. 10A is a bottom view of the BGA type semiconductor package, and FIG. 10B is a partial perspective view of FIG. 10A.

In the first modification, the BGA type semiconductor package includes a plurality of semi-circular electrode terminals 23 which are formed in and are arranged along the sides of the wiring board 11′. The first modification can be manufactured by substantially the same method as shown in FIGS. 2A through 8A and FIGS. 2B through 8B except that a plurality of circular openings are formed in the multi-layered wiring board substrate 11 as a substitute for the rectangular openings 12 (see: FIGS. 3A and 3B), and that an inner wall face of each of the circular openings is plated with copper (Cu) such that the circular openings are not stuffed with copper. In this case, the copper-plated layer may have a thickness falling within a range from 10 to 30 μm, preferably a range from 15 to 30 μm which enables the formation of the copper-plated layer to be stably carried out.

Thus, by carrying out the dicing process (see: FIGS. 7A and 7B), it is possible to obtain the semi-circular electrode terminals 23, each of which features a semi-circular end face 23₁ which is coplanar with the bottom surface of the wiring board 11′, and a semi-cylindrical face 23₁ which is formed as a recessed face in a corresponding side face of the wiring board 11′. The semi-circular electrode terminals 23 have similar functions and advantages to the flat electrode terminals 13′ of the BGA type semiconductor package of FIGS. 8A and 8B.

Second Modification

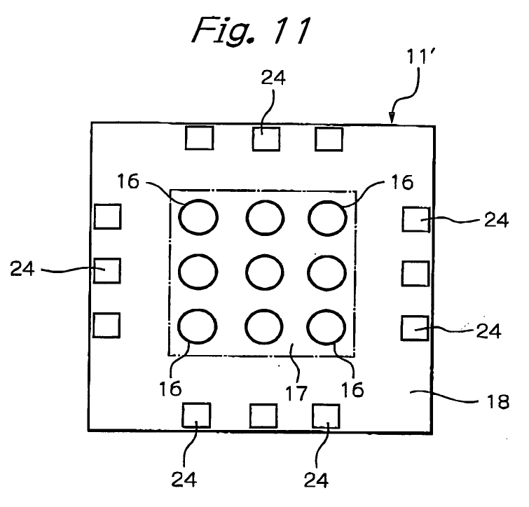

FIG. 11 shows a second modification of the BGA type semiconductor package of FIGS. 8A and 8B. Note, FIG. 11 is a bottom view of the BGA type semiconductor package.

In the second modification, the BGA type semiconductor package includes a plurality of flat electrode terminals 24 which are formed in the metal-ball exclusive area 18, and which are arranged along the sides of the wiring board 11′. The second modification can be also manufactured by substantially the same method as shown in FIGS. 2A through 8A and FIGS. 2B through 8B except that a plurality of rectangular openings are formed in a peripheral area on each of the wiring board areas WB, as a substitute for the rectangular openings 12 (see: FIGS. 3A and 3B).

In the second modification, each of the rectangular openings is stuffed with copper (Cu) in substantially the same manner as explained with reference to FIGS. 4A and 4B, resulting in production of the flat electrode terminals 24. Each of the flat electrode terminals 24 features only a flat face which is coplanar with the bottom surface of the wiring board 11′. The flat electrode terminals 24 also have similar functions and advantages to the flat electrode terminals 13′ of the BGA type semiconductor package of FIGS. 8A and 8B.

Third Modification

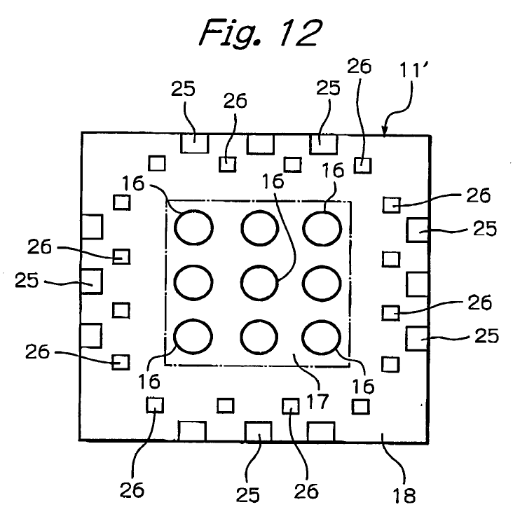

FIG. 12 shows a third modification of the BGA type semiconductor package of FIGS. 8A and 8B. Note, FIG. 12 is a bottom view of the BGA type semiconductor package.

In the third modification, the BGA type semiconductor package includes a set of flat electrode terminals 25 and a set of flat electrode terminals 26, which are formed in the metal-ball exclusive area 18 so as to be arranged along the sides of the wiring board 11′.

The formation of the flat electrode terminals 25 is carried out in substantially the same manner as the flat electrode terminals 13′ of the BGA type semiconductor package of FIGS. 8A and 8B. Thus, each of the flat electrode terminals 25 features a flat face which is coplanar with the bottom surface of the wiring board 11, and another flat face which is coplanar with a corresponding side face of the wiring board 11′.

On the other hand, the formation of the flat electrode terminals 26 is carried out in substantially the same manner as the flat electrode terminals 24 of the second modification of FIG. 11. Thus, each of the flat electrode terminals 26 features only a flat face which is coplanar with the bottom surface of the wiring board 11′.

In the third modification, the flat electrode terminals 25 and 26 also have similar functions and advantages to the flat electrode terminals 13′ of the BGA type semiconductor package of FIGS. 8A and 8B.

Fourth Modification

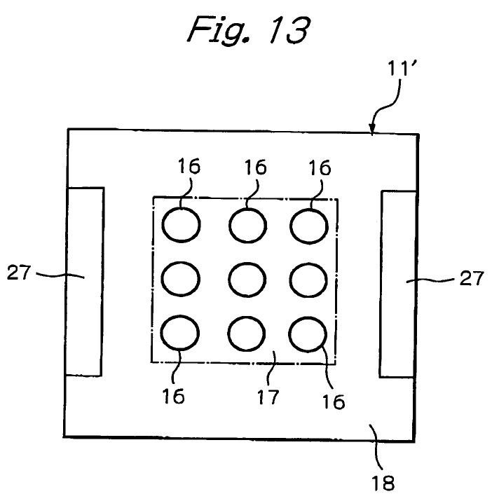

FIG. 13 shows a fourth modification of the BGA type semiconductor package according to the present invention. Note, FIG. 13 is a bottom view of the BGA type semiconductor package.

In the fourth modifications the BGA type semiconductor package includes a pair of elongated flat electrode terminals 27 which are formed in the metal-ball exclusive area 18 so as to be arranged along opposed sides of the wiring board 11′.

The formation of the elongated flat electrode terminals 27 is carried out in substantially the same manner as the flat electrode terminals 13′ of the BGA type semiconductor package of FIGS. 8A and 8B. Thus, each of the elongated flat electrode terminals 27 features a flat face which is coplanar with the bottom surface of the wiring board 11′, and another flat face which is coplanar with a corresponding side face of the wiring board 11′. Each of the elongated flat electrode terminals 27 is preferably used as an electrode terminal for a power supply or a grounding point. In this case, it is not necessary to use some of the metal balls 16 as electrode terminals for the power supply and the grounding point. The elongated flat electrode terminals 27 also have similar functions and advantages to the flat electrode terminals 13′ of the BGA type semiconductor package of FIGS. 8A and 8B.

Fifth Modification

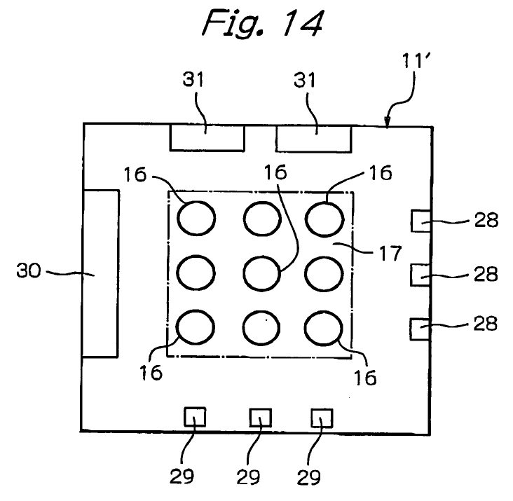

FIG. 14 shows a fifth modification of the BGA type is semiconductor package of FIGS. 8A and 8B. Note, FIG. 14 is a bottom view of the BGA type semiconductor package.

In the sixth embodiment, the BGA type semiconductor package includes a set of flat electrode terminals 28, a set of flat electrode terminals 29, a flat electrode terminal 30 and a set of flat electrode terminals 31, which are formed in the metal-ball exclusive area 18 so as to be arranged along the respective sides of the wiring board 11′.

The flat electrode terminals 28 are substantially the same as the flat electrode terminals 13′ of the BGA type semiconductor package of FIGS. 8A and 8B, and the flat electrode terminals 29 are substantially the same as the flat electrode terminals 24 of the second modification of FIG. 11. The flat electrode terminal 30 is substantially the same as the elongated flat electrode terminals 27 of the fourth modification of FIG. 13, and the flat electrode terminals 31 is also substantially the same as the elongated flat electrode terminals 27 of the fourth modification of FIG. 13 except that the flat electrode terminals 31 are shorter than the elongated flat electrode terminals 27. Each of the flat electrode terminals 30 and 31 is preferably used as an electrode terminal for a power supply or a grounding point.

As stated above, although the BGA type semiconductor s package of FIGS. 8A and 8B is formed as the FPBGA type semiconductor package, the present invention may be applied to a tape ball grid array (TBAG) type semiconductor package.

In the TBAG type semiconductor package, a tape-like multi-layered wiring substrate is substituted for the multi-layered wiring board substrate 11, and includes a plurality of insulating layers composed of a suitable resin material such as polyimide. Each of the insulating layers has a wiring pattern layer formed a top surface thereof, with two adjacent wiring pattern layers being connected to each other through a plurality of through holes formed in the insulating layer therebetween. By using the tape-like multi-layered wiring substrate, a plurality of TBAG type semiconductor packages can be manufactured in substantially the same manner as stated with reference to FIGS. 2A through 8A and FIGS. 2B through 8B. In this case, openings for forming flat electrode terminals may be formed by using a laser beam.

Also, the present invention may be applied to a so-called chip size package (CSP).

Further, in the BAG type semiconductor package of FIGS. 8A and 8B, the flat faces 13, of the flat electrode terminals 13′, which are coplanar with the bottom surface of the wiring board 11′, may be covered with a suitable insulating layer, if necessary. In this case, only the flat faces 13₂ of the flat electrode terminals 13′ are exposed to the exterior on the side faces of the wiring bard 11′.

Finally, it will be understood by those skilled in the art that the foregoing description is of preferred embodiments of the method and the devices, and that various changes and modifications may be made to the present invention without departing from the spirit and scope thereof.

1. A semiconductor package comprising:
a wiring board having a top surface, a bottom surface and a side face, said bottom surface being divided into a central area, and a peripheral area surrounding said central area;
a semiconductor chip mounted on the top surface of said wiring board so as to be electrically connected to a wiring pattern layer of said wiring board;
an array of metal balls provided as electrode terminals in the central area on the bottom surface of said wiring board; and
a plurality of additional electrode terminals provided in the peripheral area on the bottom surface and/or the side face of said wiring board.

2. The semiconductor package as set forth in claim 1, wherein said wiring pattern layer is formed on the top surface of said wiring board.

3. The semiconductor package as set forth in claim 1, further comprising an enveloper formed on the top surface of said wiring board so as to encapsulate said semiconductor chip.

4. The semiconductor package as set forth in claim 1, wherein each of said additional electrode terminals features a flat face which is coplanar with the bottom surface of said wiring board.

5. The semiconductor package as set forth in claim 1, wherein said additional electrode terminals are arranged along a side of said wiring board, each of said additional electrode terminals featuring a flat face which is coplanar with the side face of said wiring board.

6. The semiconductor package as set forth in claim 5, wherein each of said additional electrode terminals features another flat face which is coplanar with the bottom surface of said wiring board.

7. The semiconductor package as set forth in claim 1, wherein each of said additional electrode terminals is configured as an elongated electrode terminal extending along the side of said wiring board.

8. The semiconductor package as set forth in claim 7, wherein said elongated electrode terminal features a flat face which is coplanar with the bottom surface of said wiring board.

9. The semiconductor package as set forth in claim 8, wherein said elongated electrode terminal features another flat face which is coplanar with the side face of said wiring board.

10. The semiconductor package as set forth in claim 1, wherein each of said additional electrode terminals is configured as a semi-circular electrode terminal in the side of said wiring board.

11. The semiconductor package as set forth in claim 10, wherein said semi-circular electrode terminal features a semi-cylindrical face which is formed as a recessed face in the side face of the wiring board.

12. A method for manufacturing a semiconductor package, comprising:
preparing a wiring board substrate on which a wiring board area is defined, said wiring board substrate having a wiring pattern layer provided at said wiring board area, and an array of electrode pads formed in a central area on a bottom surface of said wiring board area;
mounting a semiconductor chip on a top surface of said wiring board substrate at the wiring board area;
forming a plurality of openings in said wiring board substrate along boundaries defining said wiring board area;
at least partially stuffing said openings with an electrical conductive material; and
cutting said wiring board substrate along said boundaries defining said wiring board area.

13. The semiconductor package as set forth in claim 12, further comprising encapsulating said wiring pattern layer and said semiconductor chip with a molded resin, said molded resin being simultaneously cut during the cutting of said wiring board substrate.

14. The method as set forth in claim 12, further comprising adhering metal balls to said respective electrode pads.

15. The method as set forth in claim 12, wherein the formation of said openings and the at least partially stuffing of said openings are carried out prior to the mounting of said semiconductor chip.

16. The method as set forth in claim 12, wherein the at least partially stuffing of said openings is carried out so that said openings are completely stuffed with said electrical conductive material.

17. The method as set forth in claim 12, wherein the at least partially stuffing of said openings is carried out so that an electrical conductive layer is formed on an inner face of each of said openings.

18. The method as set forth in claim 12, further comprising forming said wiring layer on the top surface of said wiring surface substrate at said wiring board area.
